(19) United States
(12) Patent Application Publication
(10) Pub. No.: US 2023/0393740 A1
(43) Pub. Date: Dec. 7, 2023

(54) FOUR WAY PSEUDO SPLIT DIE DYNAMIC RANDOM ACCESS MEMORY (DRAM) ARCHITECTURE

(71) Applicant: Intel Corporation, Santa Clara, CA (US)

(72) Inventors: Todd A. HINCK, Arlington, MA (US); Kuljit S. BAINS, Olympia, WA (US)

(21) Appl. No.: 18/235,709

(22) Filed: Aug. 18, 2023

(51) Int. Cl. G06F 3/06

(52) U.S. Cl. CPC G06F 3/061; G06F 3/0626; G06F 3/0644; G06F 3/0673

(57) ABSTRACT

Four-way pseudo split Dynamic Random Access Memory (DRAM) architectures and techniques are described. In one example, a 4-way pseudo split DRAM device includes four slices. In one example, a memory channel includes four pseudo channels, each of the four pseudo channels includes a corresponding slice of each of the plurality of DRAM devices. In one example, each of the four pseudo channels includes one slice from each of the plurality of DRAM devices.

### FIELD

Descriptions are generally related to computer memory, and more particular descriptions are related to psuedo split die dynamic random access memory (DRAM) devices and modules.

### BACKGROUND

The performance of computing systems is highly dependent on the performance of their system memory. Memory, such as DRAM, is often provided in a system via memory modules, which include multiple DRAM chips or devices. Memory modules come in a variety of form factors, such as dual inline memory modules (DIMMs), stacked memory modules, and other form factors. Various memory subsystem applications have different requirements and priorities. For example, some applications require memory subsystems that provide RAS capabilities, such as error detection and correction.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” or examples are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of an example of a 4-way pseudo-split DRAM die.

FIGS. 2A-2C are block diagrams of examples of memory modules that include 4-way pseudo-split DRAM dies.

FIG. 3 is a block diagram of an example of a memory module including 4-way pseudo split DRAM dies in which each pseudo channel corresponds to one die.

FIG. 4 is a block diagram of an example of a 4-way pseudo-split DRAM device with two slices chained together to use one output.

FIG. 5 is a block diagram of an example of a high capacity memory module configuration with 4-way pseudo split DRAM dies.

FIG. 6 illustrates a stacked memory module including 4-way pseudo split DRAM devices.

FIG. 7A illustrates an example of a dual inline memory module (DIMM) that can include 4-way pseudo split DRAM devices.

FIGS. 7B-7D illustrate examples of a compression-attached memory module (CAMM), compression connector, and a system with a CAMM that can include 4-way pseudo split DRAM devices.

FIG. 8 is a block diagram of an embodiment of a memory subsystem in which in which 4-way pseudo split DRAM devices can be included.

FIG. 9 is a block diagram of an embodiment of a computing system in which in which 4-way pseudo split DRAM devices can be included.

Descriptions of certain details and implementations follow, including a description of the figures, which may depict some or all of the embodiments described below, as well as discussing other potential embodiments or implementations of the inventive concepts presented herein.

### DETAILED DESCRIPTION

Four-way pseudo split DRAM architectures and techniques are described herein.

Single Device Data Correction (SDDC) techniques involve checking for and correcting (single or multi-bit) errors in a single device (e.g., errors affecting one entire DRAM chip). For SDDC solutions today, a memory subsystem requires two ECC devices in addition to other N DRAM devices per subchannel within a memory configuration. These ECC devices provide an equal number of bits as written or read from a data device. For example, in DDR5 (Double Data Rate version 5), 8 data devices plus 2 ECC devices per sub-channel are needed to achieve SDDC. For other memory technologies, the total number of devices varies, but conventionally 2 additional devices are used to provide ECC.

Although conventional SDDC solutions may provide sufficient reliability, availability, and serviceability (RAS) support, the total number of devices needed to support higher DRAM densities while maintaining SDDC can be prohibitively high, especially for some form factors such as stacked memory modules.

In contrast, a 4-way pseudo split DRAM architecture can enable an SDDC memory configuration with fewer devices than conventional memory subsystems.

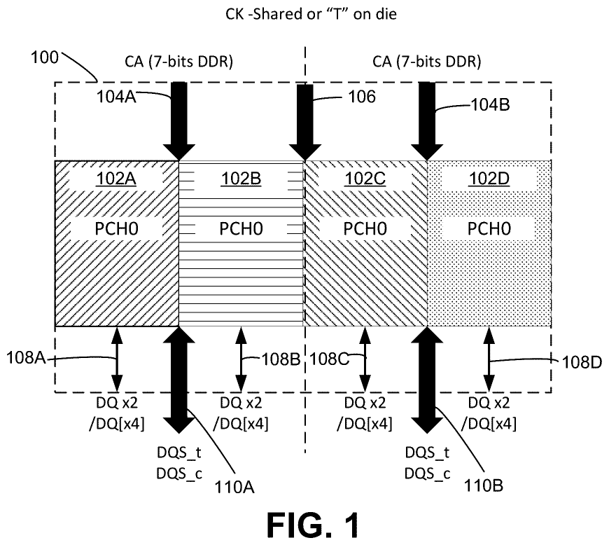

FIG. 1 is a block diagram of an example of a 4-way pseudo-split DRAM die. The DRAM device 100 includes four slices 102A-102D. Although the term “slice” is used in examples in this disclosure, a slice can also be referred to as a pseudo split die, a pseudo channel slice, or other term to indicate the DRAM die is logically split into four independent parts.

In the example illustrated in FIG. 1, the four independent slices 102A-102D of the DRAM device 100 are labeled PCH0, PCH1, PGH2, and PCH3. Different implementations of the 4-way pseudo-split DRAM die can include different clocking and command variations. For example, a 4-way pseudo-split DRAM die includes input/output (I/O) interface circuitry to couple with at least one clock signal, at least one command (CA) bus, at least one data strobe signal. In one example, two of the four PCH slices will share a bi-directional data strobe. Referring to FIG. 1, the slices 102A and 102B share the data strobe signal 110A, and the slices 102C and 102D share the data strobe signal 110B. Thus, there are two data strobe signals per die in the example of FIG. 1. In other examples, all four slices 102A-102D may share the same data strobe signal, or each of the four slices 102A-102D receives a separate data strobe signal.

In one example, two of the four PCH slices will share a CA bus. Referring to FIG. 1, the slices 102A and 102B share the CA bus 104A, and the slices 102C and 102D share the CA bus 104B. Thus, there are two CA buses per die in the example of FIG. 1. In other examples, all four slices 102A-102D may share the same CA bus, or each of the four slices 102A-102D receives a separate CA bus.

Similarly, the example illustrated in FIG. 1 depicts a block signal 106 that is shared by all the slices 102A-102D (e.g., with a “T” configuration on the die). Sharing the clock, DQS, and CA bus amongst more slices can have performance implications, while having separate clock, DQS, and CA buses for each slice increases the pin count of the DRAM die. Thus, although entirely separate or entirely shared clock, DQS, and CA buses are possible implementations, an implementation in which two of the four slices share the CA and DQS signals enables a balance between performance and pin count considerations.

Each of the slices 102A-102D includes a plurality of data lanes (e.g., data lanes 108A-108D) to couple with a data bus via the I/O interface circuitry of the DRAM device 100. In one example, each slice 102A-102D will have up to four I/O lanes (e.g., data lanes). For example, in one mode, each of the four slices 102A-102D will enable only 2 I/Os (x2) of their I/Os and in another mode each of the four slices will enable all 4 I/Os (x4) of it's I/Os. Thus, in one example, each of the slices is configurable to enable different data lane widths (e.g., 2 or 4 data lanes). In one such example, the DRAM device 100 includes one or more registers (e.g., mode registers) to store a value to enable different lane widths for each of the slices 102A-102D. Thus, in one example, the memory controller can program a register on the DRAM device 100 (and/or on a module that includes the DRAM device 100) to set the data lane width for the slices 102A-102D.

The DRAM device 100 includes banks of memory resources (e.g., arrays of memory locations). In one example, each of the slices 102A-102D includes the same number of banks. For example, each slice can include 16 banks, 32 banks, 64 banks, or another number of banks. In one example, the DRAM device 100 includes 32 banks and uses a burst length of 32. For example, the DRAM device 100 includes circuitry to enable each of the slices 102A-102D to transmit or receive data over a burst (e.g., 32 cycles or another number of cycles).

Given this DRAM die structure, in one example, an SDDC memory configuration can be achieved out of either 10 (1-Rank) or 20 (2-Rank) devices.

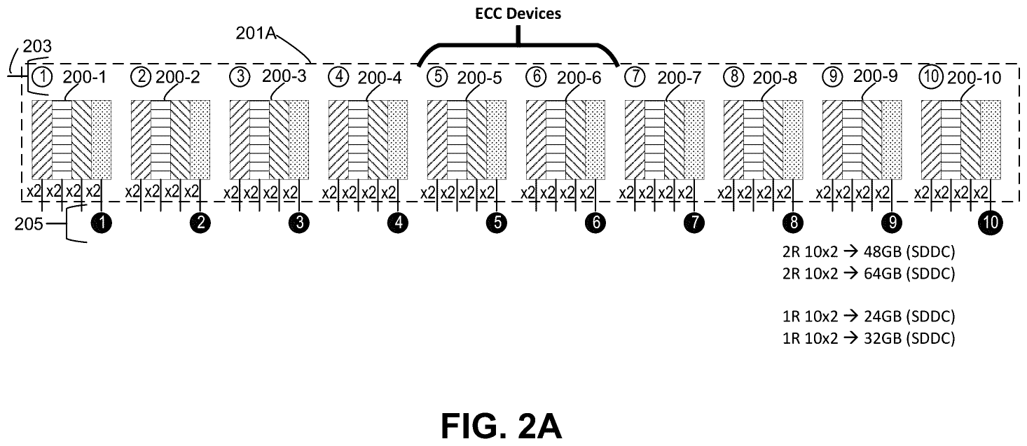

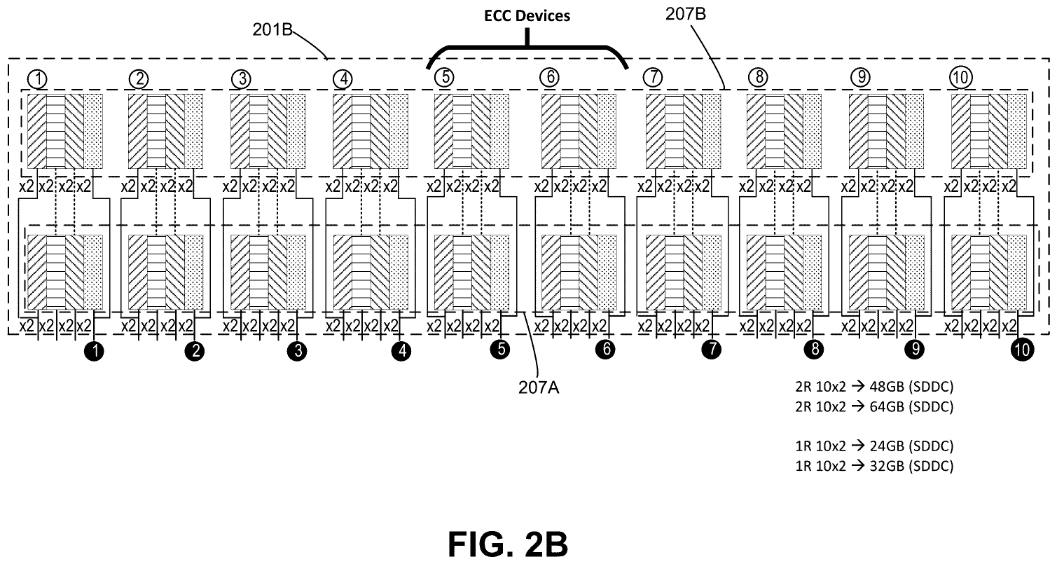

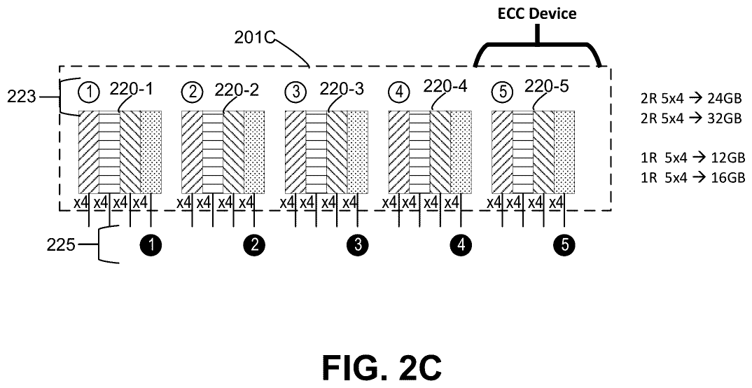

FIGS. 2A-2C illustrate block diagrams of examples of memory modules that include 4-way pseudo-split DRAM dies. The memory modules of FIGS. 2A-2C can include dual inline memory modules, stacked memory modules, or other memory modules. FIG. 2A illustrates an example of a 1-Rank (10 device) SDDC memory configuration. FIG. 2B illustrates an example of a 2-Rank (20 device) SDDC memory configuration. FIG. 2C illustrates an example of a 1-Rank (5 device) memory configuration.

Turning first to FIG. 2A, the memory module 201A includes a plurality of DRAM devices 200-1-200-10. In the example illustrated in FIG. 2A, the plurality of DRAM devices 200-1-200-10 include a plurality of data devices (e.g., DRAM devices 200-1-200-4 and DRAM devices 200-7-200-10) and ECC devices (e.g., DRAM devices 200-5 and 200-6). Each of the plurality of DRAM devices 200-1-200-10 includes four slices, such as depicted in FIG. 1.

In one example, the memory module 201-A includes a memory channel with four pseudo channels (or sub-channels). In one example, each of the four pseudo channels includes a number of slices equal to the number of DRAM devices. FIG. 2A illustrates an example in which the four pseudo channels are interleaved across the memory devices, such that each of the four pseudo channels includes a corresponding slice of each of the plurality of DRAM devices 200-1-200-10. For example, the numbered circles above the DRAM devices 200-1-200-10 (indicated with the brace 203) show the slices corresponding to one pseudo channel (e.g., PCH0). The numbered circles below the DRAM devices 200-1-200-10 (indicated with the brace 205) show the slices corresponding to another pseudo channel (e.g., PCH3). Thus, the numbered circles show two of the four pseudo channels; in this example, the other slices similarly correspond to pseudo channels (e.g., the second slices correspond to PCH 1, and the third slices correspond to PCH 2), however, the remaining two pseudo channels are not labeled in FIG. 2A in order to not obscure the clarity of the drawing.

Accordingly, FIG. 2A depicts an example with ten slices per pseudo channel: 1 slice from each of the 8 data DRAM devices 200-1-200-4 and 200-7-200-10, and 1 slice from each of the 2 ECC DRAM devices 200-5 and 200-6. In one example, each slice transmits or receives data over a burst. Consider an example in which each slice outputs (or inputs) a burst for 32 cycles. If each slice has 2 I/Os (e.g., 2 data lanes, shown with a x2) then each slice output 64 bits. Therefore, in this example, 8 devices×64bits=512 bits or 64 Bytes per burst. In one such example, the ECC devices 100-5 and 100-6 are each outputting 64-bits per burst, resulting in SDDC operation.

FIG. 2A shows a single rank, however, a memory module with 2 ranks is possible. For example, another 10 devices can be added to these devices to get a 2-rank memory configuration. FIG. 2B illustrates an example of the module similar to the module 201A of FIG. 2A, but with a second rank. A memory rank is a set of DRAM devices connected to the same chip select, which are therefore accessed simultaneously. In the example illustrated in FIG. 2B, there are two ranks 207A and 207B of DRAM devices, each rank with ten devices, for a total of twenty DRAM devices. In the illustrated example, each of the four pseudo channels includes a slice from each of the 20 devices. Therefore, each pseudo channel includes 20 slices. In the example illustrated in FIG. 2B, each rank includes 8 data DRAM devices and 2 ECC DRAM devices. In one such example, from a capacity perspective, we can get 48 GB with 24 Gb DRAM technology.

The example in FIG. 2B illustrates x2 slices (e.g., each slice with 2 data lanes enabled), however, other examples can include slices with different data lane widths. DDR DRAMs have traditionally supported 1X and 1/2X density DIMM configurations. For example, in DDR5, this was analogous to x4 and x8 devices. If you consider FIGS. 2A and 2B to be 1X density configurations (similar to a x4 memory configuration), FIG. 2C illustrates an example memory module with 4-way pseudo split DRAM dies having a 1/2X density (similar to a x8 memory configuration relative to a x4 memory configuration).

Turning now to FIG. 2C, like in the examples of FIGS. 2A and 2B, each memory channel includes 4 pseudo channels or sub channels. The memory module 201C includes one rank of five 4-way pseudo split DRAM devices 220-1-220-5. The DRAM devices 220-1-220-5 of the memory module 201C include four data DRAM devices 220-1-220-4 and one ECC DRAM device 220-5. Each of the DRAM devices 220-1-220-5 include 4 slices. The numbered circles illustrate two of the four pseudo channels to highlight the five slices used for each pseudo channel. For example, the numbered circles above the DRAM devices 220-1-220-5 (indicated with the brace 223) show the slices corresponding to one pseudo channel (e.g., PCH0). The numbered circles below the DRAM devices 220-1-220-5 (indicated with the brace 225) show the slices corresponding to another pseudo channel (e.g., PCH3). Thus, the numbered circles show two of the four pseudo channels; in this example, the other slices similarly correspond to pseudo channels (e.g., the second slices correspond to PCH1, and the third slices correspond to PCH2), however, the remaining two pseudo channels are not labeled in FIG. 2C in order to not obscure the clarity of the drawing.

In the example illustrated in FIG. 2C, each of the slices includes 4 data lanes (shown with the x4 on each slice). Consider an example in which each slice outputs (or inputs) a burst for 32 cycles. If each slice has 4 I/Os (e.g., 4 data lanes, shown by the x4), then each slice outputs (or inputs) 128 bits. Therefore, in one such example, 4 devices x 128bits=512 bits or 64 Bytes per burst. In one example, the ECC DRAM device 220-5 outputs 128-bits, which enables detection capability (e.g., 100% detection capability, but not SDDC). In one example, another 5 devices can be added to these devices to get a 2-rank memory configuration. In one such example, from a capacity perspective, 24 GB can be achieved with 24 Gb DRAM technology.

Thus, FIGS. 2A-2C illustrate examples of memory modules with 4-way pseudo split DRAM devices, wherein each DRAM device is split into four slices, and the four pseudo channels are interleaved across the DRAM devices of the module. The memory modules of FIGS. 2A-2C all include ECC DRAM devices to achieve error detection and/or SDDC. However, other memory modules may not include ECC devices. For example, for client applications, there generally is not demand to pull data from a device matched with an ECC device. Therefore, rather than interleaving four pseudo channels, in one example, a memory channel can include four pseudo channels, where each pseudo channel pulls data all from one of the devices.

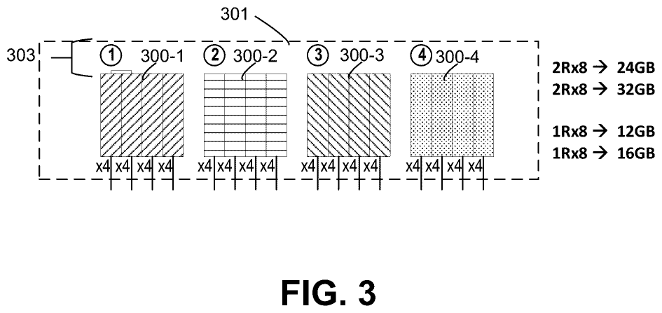

For example, FIG. 3 is a block diagram of an example of a memory module including 4-way pseudo split DRAM dies in which each pseudo channel corresponds to one die. In the example illustrated in FIG. 3, the memory module 301 includes four DRAM devices 300-1-300-4. The four DRAM devices 300-1-300-4 are all data DRAM devices, and each includes four slices. Instead of each pseudo channel or sub channel including a slice from each of the devices (like in examples of FIGS. 2A-2C), FIG. 3 illustrates an example in which each of the pseudo channels corresponds to four slices all from a single one of the DRAM devices 300-1-300-4. For example, the numbered circles (shown with the brace 303) illustrate the four pseudo channels. One pseudo channel (e.g., PCH0) corresponds to the four slices of the DRAM device 300-1, a second pseudo channel (e.g., PCH1) corresponds to the four slices of the DRAM device 300-2, a third pseudo channel (e.g., PCH2) corresponds to the four slices of the DRAM device 300-3, and a fourth pseudo channel (e.g., PCH3) corresponds to the four slices of the DRAM device 300-4.

In the illustrated example, each of the slices has 4 data lanes (shown with the x4). Consider an example in which each slice outputs (or inputs) a burst for 32 cycles. If each slice has 4 I/Os (e.g., 4 data lanes, shown by the x4), then each slice outputs (or inputs) 128 bits. Therefore, each device, 4 slices x 128 bits=512bits or 64 Bytes per burst. In one example, another 4 devices can be added to these devices to get a 2-rank memory configuration. Thus, FIG. 3 illustrates an example in which each of the four pseudo channels includes four slices from a single one of the plurality of DRAM devices.

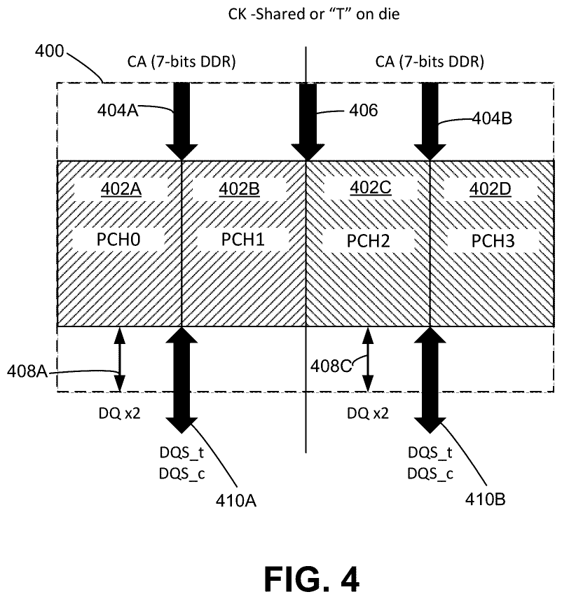

FIG. 4 is a block diagram of an example of a 4-way pseudo-split DRAM device with two slices chained together to use one output. Like the example in FIG. 1, the DRAM device 400 of FIG. 4 includes four slices 402A, 402B, 402C, and 402D. In the example illustrated in FIG. 4, the DRAM device 400 includes one shared clock signal 406, two CA buses 404A and 404B (one CA bus for two of slices), and two data strobe signals 410A and 410B (one for two of the slices). As explained above with respect to FIG. 1, the example of FIG. 4 illustrates one way of sharing the clock, DQS, and command bus signal lines; other command bus, clocking, and data strobe variations are also possible for the 4-way pseudo split DRAM device.

Unlike the example in FIG. 1, FIG. 4 depicts a 4-way pseudo split DRAM device in which two of the four slices share one of those slice's data lanes. Two slices are chained together to use only one output. For example, the slices 402A and 402B are chained together and use the data lanes 408A of slice 402A. Similarly, the slices 402C and 402D are chained together and use the data lanes 408C of slice 402C. Thus, the four slices are paired together such that each pair of slices share the I/Os of one slice. In one such example, chaining together two of four slices allows for 2X density memory configuration by allowing 2 I/Os (e.g., 2 data lanes, shown by the x2) to be used for 2 slices.

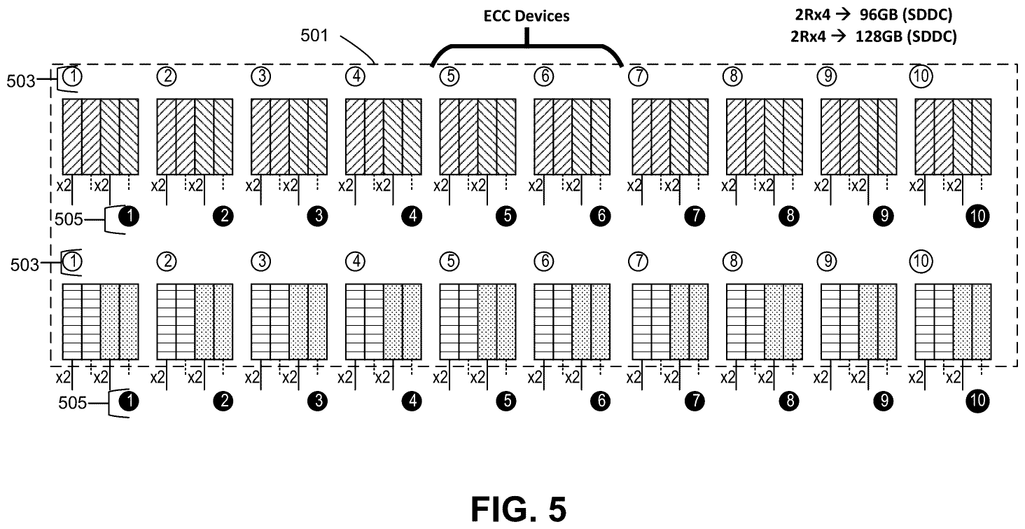

Thus, in the example illustrated in FIG. 4, one slice is chained to another slice, and those slices only use the 2 I/Os from one of the chained together slices. In one such example, a memory module including DRAM devices configured as in FIG. 4 is a high-capacity memory module (e.g., 40 devices per DIMM) that enables 2X the capacity (e.g., from 96 GB and 128 GB, or another capacity). In one such example, the high capacity DIMM does not interleave the 4 pseudo channels per device, but rather only 2 pseudo channels per device. For example, FIG. 5 illustrates an example of a high capacity memory module configuration with 4-way pseudo split DRAM dies. The memory module of FIG. 5 can be a DIMM, stacked memory module, or other memory module.

The memory module 501 of FIG. 5 illustrates one rank with 20 4-way pseudo split DRAM devices. Each row of DRAM devices shown in FIG. 5 includes eight data DRAM devices and 2 ECC DRAM devices. Each of the DRAM devices shown in FIG. 5 includes four slices with two of those slices sharing data lanes (the solid lines from each DRAM device illustrate enabled data lanes, and the doted lines from each of the DRAM devices illustrate unused data lanes). Thus, each of the DRAM devices shown in FIG. 5 include 2 x2 data lanes. Numbered circles are shown to illustrate two of the four pseudo channels. For example, a first pseudo channel (e.g., PCH0) is shown with the circled numbers indicated by brace 503, and includes 20 slices, one from each of the DRAM devices. Another pseudo channel (e.g., PCH3) is shown with the circled numbers indicated by the brace 505, and includes 20 slices, one from each of the DRAM devices. Similarly, in this example, the other two channels each include 20 slices, one from each of the DRAM devices.

Although one rank is shown in FIG. 5, a second rank of 20 devices can be added for a total of 40 4-way pseudo-split DRAM devices. In one such example, the memory module 501 includes an address repeater/clock repeater (e.g., a registered clock driver (RCD)) given the large number of devices that need CA and clock connections. In one example, the memory configuration shown in FIG. 5 with a second rank could be stacked in 4 packages, each with 10 devices. In another example, each device can be packaged in a single die package (SDP) each placed separately on a DIMM.

Thus, FIGS. 1-5 illustrate various examples of 4-way pseudo split DRAM dies and modules including 4-way pseudo split DRAM dies. In FIGS. 1-3, shading is used to depict the four different slices as they correspond to the four pseudo channels of a memory channel, where slices having the same shading correspond to the same pseudo channel. In FIGS. 4 and 5, the same shading is used for two of the four slices of a 4-way pseudo split DRAM die to indicate that those slices are sharing one of the slice's data lanes.

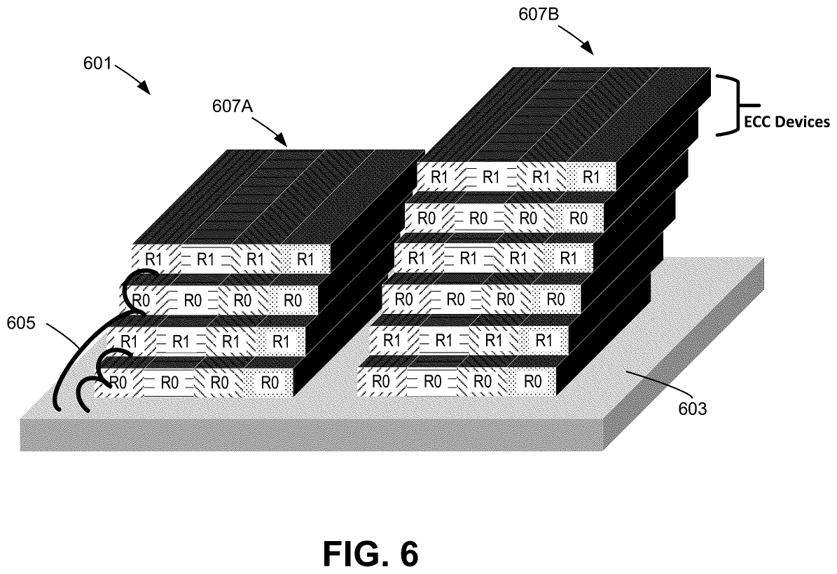

FIG. 6 illustrates a stacked memory module including 4-way pseudo split DRAM devices. In some memory subsystems, DRAM is stacked close to the processor. Using 4-way pseudo split DRAM devices enables minimizing the number of packages by enabling a memory channel with fewer dies, while still making SDDC possible. FIG. 6 illustrates one package 601, each package holding ten 4-way pseudo split DRAM dies. For example, the package 601 includes a substrate 603 over which two stacks 607A and 607B of pseudo split DRAM dies are disposed. Wired bonds 605 are shown, coupling the stacked DRAM devices. One stack 607A of DRAM devices includes four data DRAM devices, and a second stack 607B includes four data DRAM devices and two ECC DRAM devices. In one such example, a memory channel includes two such packages (e.g., two of the packages 601) for a total of twenty 4-way pseudo split DRAM devices. Thus, a stacked memory module can include two or more packages, each including a plurality of 4-way pseudo split DRAM devices. Note that although shown in a stacked configuration, 4-way pseudo-split DRAM dies can also be packaged in a standard SDP package or laid out 20 devices on a DIMM.

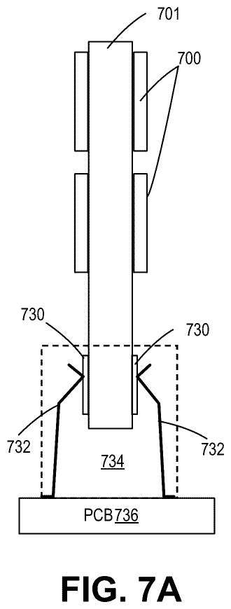

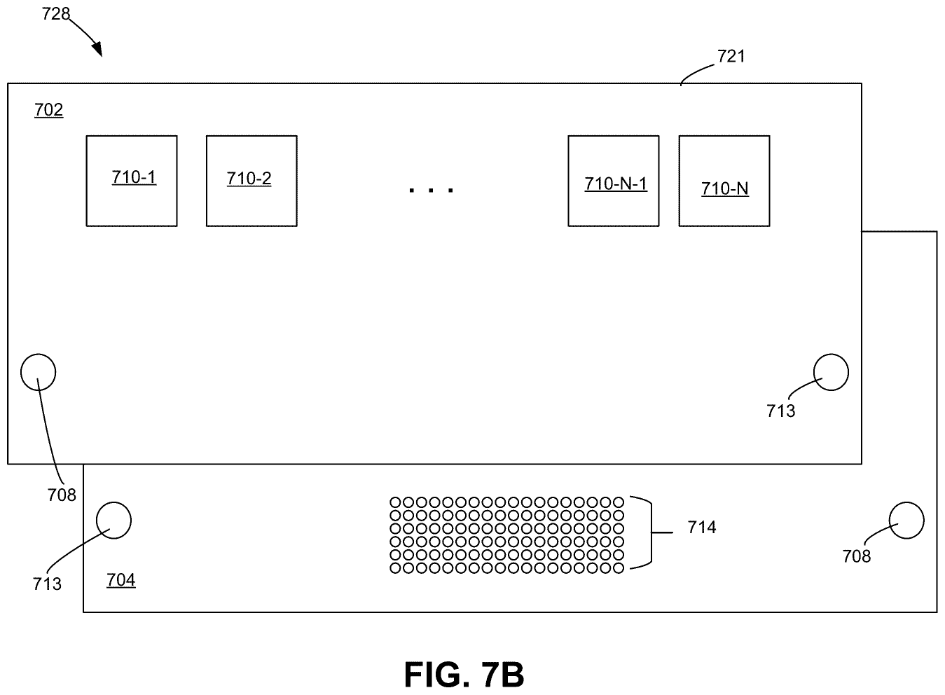

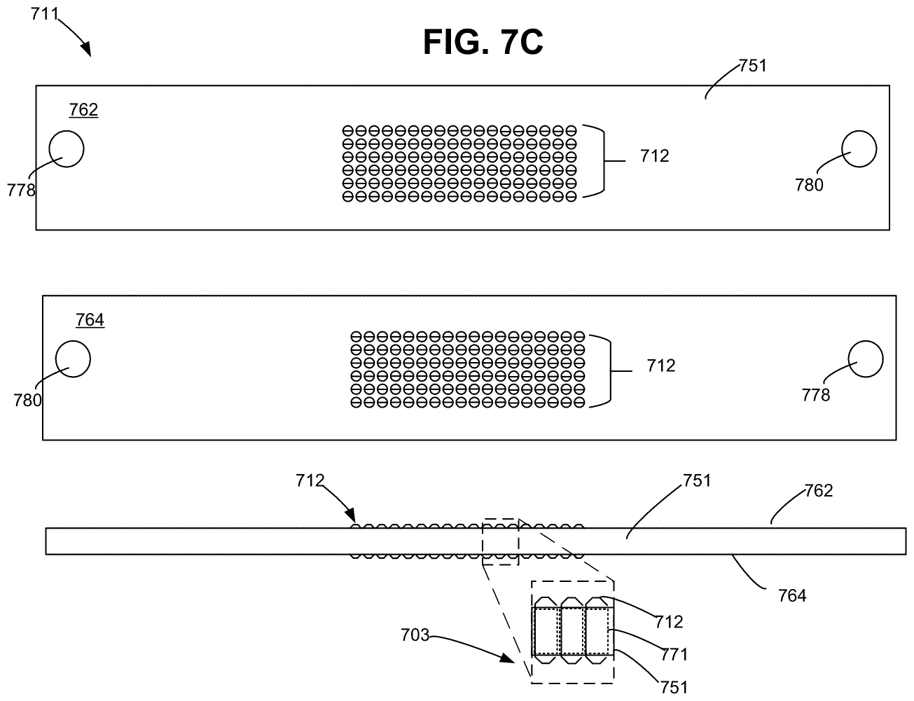

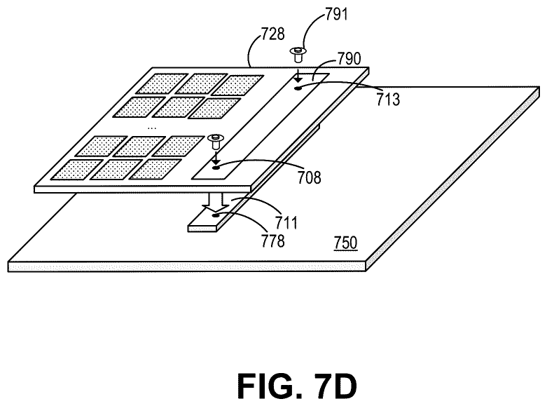

FIG. 7A illustrates an example of a dual inline memory module (DIMM) that can include 4-way pseudo split DRAM devices. The DIMM 701 can be any of a variety of types DIMMs, such as an unbuffered or unregistered DIMM (UDIMM), a registered DIMM (RDIMM), a load reduced DIMM (LRDIMM), an enhanced load reduced DIMM (eLRDIMM), a multi-ranked buffered DIMM (MRDIMM), or other type of DIMM. The DIMM 701 can be inserted or seated into the socket of the DIMM connector 734 on the PCB or motherboard 736. The connector 734 includes pins 732 that make contact with pins 730 of the DIMM 701. The pins 730 couple with the DRAM chips 700 on the DIMM 701 via conductive traces on or in the DIMM 701. In this way, signals can be transmitted to and from the DRAM chips 700 via the connector 734. The DRAM chips 700 can be in accordance with any of DRAM devices described herein.

FIGS. 7B-7D illustrate examples of a compression-attached memory module (CAMM), compression connector, and a system with a CAMM that can include 4-way pseudo split DRAM devices. FIG. 7B illustrates front and back faces of an example of a compression-attached memory module (CAMM) 728 that can include 4-way pseudo split DRAM die. The CAMM 728 includes a PCB 721 and memory chips or dies 710-1-710-N on one or both faces 702,704 of the PCB 721. The memory chips 710-1-710-N can be in accordance with any example described herein. The memory chips 710-1-710-N are coupled with conductive contacts 714 via conductive traces in or on the PCB 721. The conductive contacts 714 are to couple with corresponding conductive contacts on a compression connector (e.g., a compression mount technology (CMT) connector), such as the compression connector 711 of FIG. 7C, discussed below. In one example, compressible conductive contacts are between the contacts 714 of the memory module 728 and the contacts of the compression connector.

The memory module 728 includes holes 708 and 713 that correspond to holes in the motherboard and the compression connector. The holes 708, 713 are to receives fasteners, such as screws, to compressibly attach the memory module 728 to the motherboard via the compression connector.

FIG. 7C illustrates front, back, and side views of an example of a compression mount technology (CMT) connector 711. The CMT connector 711 includes a housing 751 to provide support for the contacts 712. The contacts 712 extend through the CMT connector 711 and are exposed at both faces 762 and 764 of the CMT connector 711. In one example, the contacts 712 are compressible pins, such as the C-shaped pins. In other example, the contacts 712 are another compressible pin shape, such as a spring-shape, an S-shape, or pins having other shapes that can be compressed.

In one example, the pins are supported and kept in alignment by an array of holes or openings in the housing. In the example illustrated in FIG. 7B, each of the pins 712 is contained in a cylindrical hole or enclosure that extends through the housing 751. For example, magnified view 703 shows an example of a CMT connector 711 with openings 771 in the housing 751 that contain or include C-shaped pins 712. However, other shapes of holes or enclosures may be used to support the conductive contacts 712. In one example, the pressure applied by the fasteners through the holes 778 and 780 to the CMT connector 711, the motherboard, and the memory module 728 cause the contacts 712 to compress slightly into the holes in which they are enclosed. For example, FIG. 7D illustrates a system including a motherboard 750 (or other PCB or substrate) and a CMT connector 711 via which a CAMM 728 can be compressibly mounted on the motherboard 750 with fasteners 791. In one example, the system can include an additional layer 790, such as a plate, between the fasteners 791 and the CAMM 728. Although FIGS. 7B-7D illustrate only two holes in the CAMM 728 and CMT connector 711 to receive fasteners to compressibly couple the CAMM 728 to the motherboard or other PCB or substrate, other examples can include fewer than two or more than two holes/fasteners. Also, although a single CMT connector 711 is shown, in other examples, the system includes more than one CMT connector via which the CAMM is connected to the underlying PCB (e.g., two, three, or another number of CMT connectors).

FIGS. 6 and 7A-7D illustrate examples of memory module form factors that can include 4-way pseudo split DRAM die, however, the 4-way pseudo split DRAM die discussed herein can be implemented using a variety of form factors and packaging techniques.

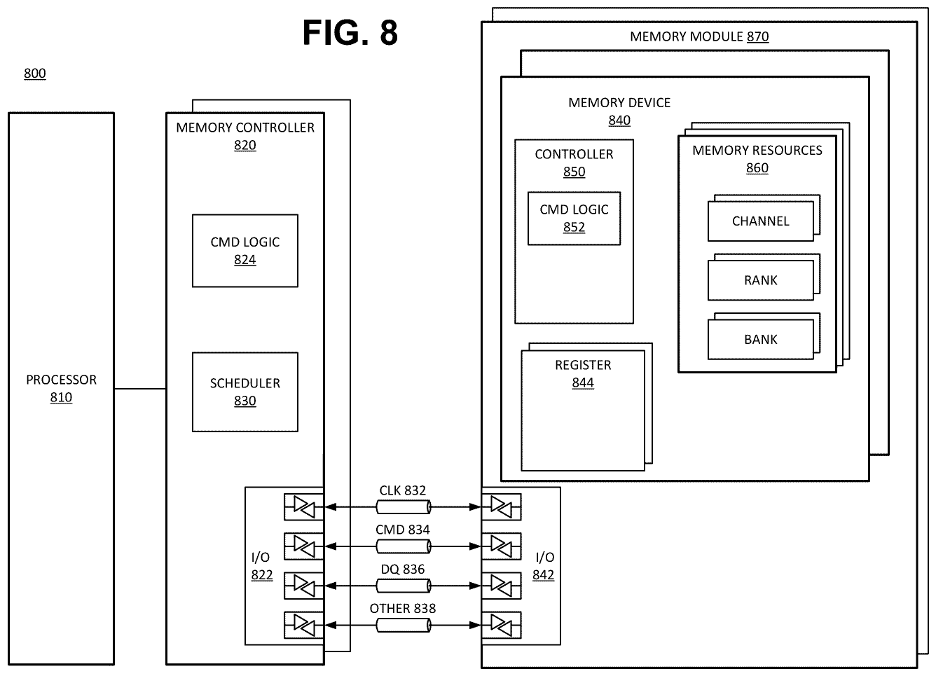

FIG. 8 is a block diagram of an embodiment of a memory subsystem in which 4-way pseudo split DRAM devices can be included. System 800 includes a processor and elements of a memory subsystem in a computing device. Processor 810 represents a processing unit of a computing platform that may execute an operating system (OS) and applications, which can collectively be referred to as the host or the user of the memory. The OS and applications execute operations that result in memory accesses. Processor 810 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 800 can be implemented as an SOC (system on a chip) or be implemented with standalone components.

Reference to memory devices can apply to different memory types. “Memory devices” often refers to volatile memory technologies. Volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, originally published in September 2012 by JEDEC), DDR5 (DDR version 5, originally published in July 2020), DDR6, LPDDR3 (Low Power DDR version 3, JESD209-3B, August 2013 by JEDEC), LPDDR4 (LPDDR version 4, JESD209-4, originally published by JEDEC in August 2014), LPDDR5 (LPDDR version 5, JESD209-5A, originally published by JEDEC in January 2020), WIO2 (Wide Input/Output version 2, JESD229-2 originally published by JEDEC in August 2014), HBM (High Bandwidth Memory, JESD235, originally published by JEDEC in October 2013), HBM2 (HBM version 2, JESD235C, originally published by JEDEC in January 2020), or HBM3 (HBM version 3 currently in discussion by JEDEC), or others or combinations of memory technologies, and technologies based on derivatives or extensions of such specifications. The JEDEC standards are available at www.jedec.org.

Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one embodiment, a system with volatile memory that needs to be refreshed can also include nonvolatile memory.

Memory controller 820 represents one or more memory controller circuits or devices for system 800. Memory controller 820 represents control logic that generates memory access commands in response to the execution of operations by processor 810. Memory controller 820 accesses one or more memory devices 840. Memory devices 840 can be DRAM devices in accordance with any referred to above. In one embodiment, memory devices 840 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one embodiment, settings for each channel are controlled by separate mode registers or other register settings. In one embodiment, each memory controller 820 manages a separate memory channel, although system 800 can be configured to have multiple channels managed by a single controller, or to have multiple controllers on a single channel. In one embodiment, memory controller 820 is part of host processor 810, such as logic implemented on the same die or implemented in the same package space as the processor.

Memory controller 820 includes I/O interface logic 822 to couple to a memory bus, such as a memory channel as referred to above. I/O interface logic 822 (as well as I/O interface logic 842 of memory device 840) can include pins, pads, connectors, signal lines, traces, or wires, or other hardware to connect the devices, or a combination of these. I/O interface logic 822 can include a hardware interface. As illustrated, I/O interface logic 822 includes at least drivers/transceivers for signal lines. Commonly, wires within an integrated circuit interface couple with a pad, pin, or connector to interface signal lines or traces or other wires between devices. I/O interface logic 822 can include drivers, receivers, transceivers, or termination, or other circuitry or combinations of circuitry to exchange signals on the signal lines between the devices. The exchange of signals includes at least one of transmit or receive. While shown as coupling I/O 822 from memory controller 820 to I/O 842 of memory device 840, it will be understood that in an implementation of system 800 where groups of memory devices 840 are accessed in parallel, multiple memory devices can include I/O interfaces to the same interface of memory controller 820. In an implementation of system 800 including one or more memory modules 870, I/O 842 can include interface hardware of the memory module in addition to interface hardware on the memory device itself. Other memory controllers 820 will include separate interfaces to other memory devices 840.

The bus between memory controller 820 and memory devices 840 can be implemented as multiple signal lines coupling memory controller 820 to memory devices 840. The bus may typically include at least clock (CLK) 832, command/address (CMD) 834, and write data (DQ) and read data (DQ) 836, and zero or more other signal lines 838. In one embodiment, a bus or connection between memory controller 820 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one embodiment, independent channels have different clock signals, C/A buses, data buses, and other signal lines. Thus, system 800 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 820 and memory devices 840. An example of a serial bus technology is 8B10B encoding and transmission of high-speed data with embedded clock over a single differential pair of signals in each direction. In one embodiment, CMD 834 represents signal lines shared in parallel with multiple memory devices. In one embodiment, multiple memory devices share encoding command signal lines of CMD 834, and each has a separate chip select (CS_n) signal line to select individual memory devices.

It will be understood that in the example of system 800, the bus between memory controller 820 and memory devices 840 includes a subsidiary command bus CMD 834 and a subsidiary bus to carry the write and read data, DQ 836. In one embodiment, the data bus can include bidirectional lines for read data and for write/command data. In another embodiment, the subsidiary bus DQ 836 can include unidirectional write signal lines for write and data from the host to memory and can include unidirectional lines for read data from the memory to the host. In accordance with the chosen memory technology and system design, other signals 838 may accompany a bus or sub bus, such as strobe lines DQS. Based on design of system 800, or implementation if a design supports multiple implementations, the data bus can have more or less bandwidth per memory device 840. For example, the data bus can support memory devices that have either a x32 interface, a x16 interface, a x8 interface, or other interface. The convention “xW,” where W is an integer that refers to an interface size or width of the interface of memory device 840, which represents a number of signal lines to exchange data with memory controller 820. The interface size of the memory devices is a controlling factor on how many memory devices can be used concurrently per channel in system 800 or coupled in parallel to the same signal lines. In one embodiment, high bandwidth memory devices, wide interface devices, or stacked memory configurations, or combinations, can enable wider interfaces, such as a x128 interface, a x256 interface, a x512 interface, a x1024 interface, or other data bus interface width.

In one embodiment, memory devices 840 and memory controller 820 exchange data over the data bus in a burst, or a sequence of consecutive data transfers. The burst corresponds to a number of transfer cycles, which is related to a bus frequency. In one embodiment, the transfer cycle can be a whole clock cycle for transfers occurring on a same clock or strobe signal edge (e.g., on the rising edge). In one embodiment, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length 8 (BL8), and each memory device 840 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 840 represent memory resources for system 800. In one embodiment, each memory device 840 is a separate memory die. In one embodiment, each memory device 840 can interface with multiple (e.g., 2) channels per device or die. Each memory device 840 includes I/O interface logic 842, which has a bandwidth determined by the implementation of the device (e.g., x16 or x8 or some other interface bandwidth). I/O interface logic 842 enables the memory devices to interface with memory controller 820. I/O interface logic 842 can include a hardware interface and can be in accordance with I/O 822 of memory controller, but at the memory device end. In one embodiment, multiple memory devices 840 are connected in parallel to the same command and data buses. In another embodiment, multiple memory devices 840 are connected in parallel to the same command bus and are connected to different data buses. For example, system 800 can be configured with multiple memory devices 840 coupled in parallel, with each memory device responding to a command, and accessing memory resources 860 internal to each. For a Write operation, an individual memory device 840 can write a portion of the overall data word, and for a Read operation, an individual memory device 840 can fetch a portion of the overall data word. As non-limiting examples, a specific memory device can provide or receive, respectively, 8 bits of a 128-bit data word for a Read or Write transaction, or 8 bits or 16 bits (depending for a x8 or a x16 device) of a 256-bit data word. The remaining bits of the word will be provided or received by other memory devices in parallel.

In one embodiment, memory devices 840 are disposed directly on a motherboard or host system platform (e.g., a PCB (printed circuit board) on which processor 810 is disposed) of a computing device. In one embodiment, memory devices 840 can be organized into memory modules 870. In one embodiment, memory modules 870 represent dual inline memory modules (DIMMs).

In one embodiment, memory modules 870 represent other organization of multiple memory devices to share at least a portion of access or control circuitry, which can be a separate circuit, a separate device, or a separate board from the host system platform. Memory modules 870 can include multiple memory devices 840, and the memory modules can include support for multiple separate channels to the included memory devices disposed on them. In another embodiment, memory devices 840 may be incorporated into the same package as memory controller 820, such as by techniques such as multi-chip-module (MCM), package-on-package, through-silicon via (TSV), or other techniques or combinations. Similarly, in one embodiment, multiple memory devices 840 may be incorporated into memory modules 870, which themselves may be incorporated into the same package as memory controller 820. It will be appreciated that for these and other embodiments, memory controller 820 may be part of host processor 810.

Memory devices 840 each include memory resources 860. Memory resources 860 represent individual arrays of memory locations or storage locations for data. Typically, memory resources 860 are managed as rows of data, accessed via wordline (rows) and bitline (individual bits within a row) control. Memory resources 860 can be organized as separate channels, ranks, and banks of memory. Channels may refer to independent control paths to storage locations within memory devices 840. A rank refers to memory devices coupled with the same chip select. Ranks may refer to common locations across multiple memory devices (e.g., same row addresses within different devices). Banks may refer to arrays of memory locations within a memory device 840. In one embodiment, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one embodiment, memory devices 840 include one or more registers 844. Register 844 represents one or more storage devices or storage locations that provide configuration or settings for the operation of the memory device. In one embodiment, register 844 can provide a storage location for memory device 840 to store data for access by memory controller 820 as part of a control or management operation. In one embodiment, register 844 includes one or more Mode Registers. In one embodiment, register 844 includes one or more multipurpose registers. The configuration of locations within register 844 can configure memory device 840 to operate in different “modes,” where command information can trigger different operations within memory device 840 based on the mode. Additionally, or in the alternative, different modes can also trigger different operation from address information or other signal lines depending on the mode. Settings of register 844 can indicate configuration for I/O settings (e.g., timing, termination or ODT (on-die termination), driver configuration, or other I/O settings).

Memory device 840 includes controller 850, which represents control logic within the memory device to control internal operations within the memory device. For example, controller 850 decodes commands sent by memory controller 820 and generates internal operations to execute or satisfy the commands. Controller 850 can be referred to as an internal controller and is separate from memory controller 820 of the host. Controller 850 can determine what mode is selected based on register 844 and configure the internal execution of operations for access to memory resources 860 or other operations based on the selected mode. Controller 850 generates control signals to control the routing of bits within memory device 840 to provide a proper interface for the selected mode and direct a command to the proper memory locations or addresses. Controller 850 includes command logic 852, which can decode command encoding received on command and address signal lines. Thus, command logic 852 can be or include a command decoder. With command logic 852, memory device can identify commands and generate internal operations to execute requested commands.

Referring again to memory controller 820, memory controller 820 includes command (CMD) logic 824, which represents logic or circuitry to generate commands to send to memory devices 840. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 840, memory controller 820 can issue commands via I/O 822 to cause memory device 840 to execute the commands. In one embodiment, controller 850 of memory device 840 receives and decodes command and address information received via I/O 842 from memory controller 820. Based on the received command and address information, controller 850 can control the timing of operations of the logic and circuitry within memory device 840 to execute the commands. Controller 850 is responsible for compliance with standards or specifications within memory device 840, such as timing and signaling requirements. Memory controller 820 can implement compliance with standards or specifications by access scheduling and control.

Memory controller 820 includes scheduler 830, which represents logic or circuitry to generate and order transactions to send to memory device 840. From one perspective, the primary function of memory controller 820 could be said to schedule memory access and other transactions to memory device 840. Such scheduling can include generating the transactions themselves to implement the requests for data by processor 810 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 820 typically includes logic such as scheduler 830 to allow selection and ordering of transactions to improve performance of system 800. Thus, memory controller 820 can select which of the outstanding transactions should be sent to memory device 840 in which order, which is typically achieved with logic much more complex that a simple first-in first-out algorithm. Memory controller 820 manages the transmission of the transactions to memory device 840, and manages the timing associated with the transaction. In one embodiment, transactions have deterministic timing, which can be managed by memory controller 820 and used in determining how to schedule the transactions with scheduler 830.

In one example, the memory module(s) 870 can include 4-way pseudo split DRAM devices in accordance with examples described herein.

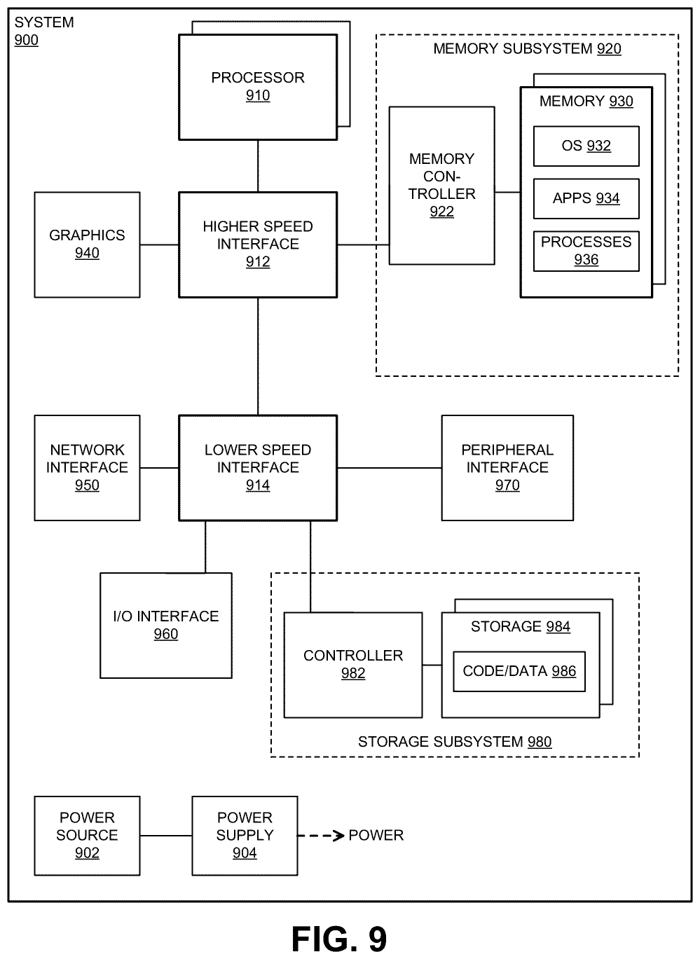

FIG. 9 is a block diagram of an embodiment of a computing system in which 4-way pseudo split DRAM devices can be included. System 900 represents a computing device in accordance with any embodiment described herein, and can be a laptop computer, a desktop computer, a tablet computer, a server, a gaming or entertainment control system, a scanner, copier, printer, routing or switching device, embedded computing device, a smartphone, a wearable device, an internet-of-things device, or other electronic device.

System 900 includes processor 910, which provides processing, operation management, and execution of instructions for system 900. Processor 910 can include any type of microprocessor, central processing unit (CPU), graphics processing unit (GPU), processing core, or other processing hardware to provide processing for system 900, or a combination of processors. Processor 910 controls the overall operation of system 900, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one embodiment, system 900 includes interface 912 coupled to processor 910, which can represent a higher speed interface or a high throughput interface for system components that needs higher bandwidth connections, such as memory subsystem 920 or graphics interface components 940. Interface 912 represents an interface circuit, which can be a standalone component or integrated onto a processor die. Where present, graphics interface 940 interfaces to graphics components for providing a visual display to a user of system 900. In one embodiment, graphics interface 940 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one embodiment, the display can include a touchscreen display. In one embodiment, graphics interface 940 generates a display based on data stored in memory 930 or based on operations executed by processor 910 or both. In one embodiment, graphics interface 940 generates a display based on data stored in memory 930 or based on operations executed by processor 910 or both.

Memory subsystem 920 represents the main memory of system 900 and provides storage for code to be executed by processor 910, or data values to be used in executing a routine. Memory subsystem 920 can include one or more memory devices 930 such as read-only memory (ROM), flash memory, one or more varieties of random-access memory (RAM) such as DRAM, or other memory devices, or a combination of such devices. Memory 930 stores and hosts, among other things, operating system (OS) 932 to provide a software platform for execution of instructions in system 900. Additionally, applications 934 can execute on the software platform of OS 932 from memory 930. Applications 934 represent programs that have their own operational logic to perform execution of one or more functions. Processes 936 represent agents or routines that provide auxiliary functions to OS 932 or one or more applications 934 or a combination. OS 932, applications 934, and processes 936 provide software logic to provide functions for system 900. In one embodiment, memory subsystem 920 includes memory controller 922, which is a memory controller to generate and issue commands to memory 930. It will be understood that memory controller 922 could be a physical part of processor 910 or a physical part of interface 912. For example, memory controller 922 can be an integrated memory controller, integrated onto a circuit with processor 910.

While not specifically illustrated, it will be understood that system 900 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one embodiment, system 900 includes interface 914, which can be coupled to interface 912. Interface 914 can be a lower speed interface than interface 912. In one embodiment, interface 914 represents an interface circuit, which can include standalone components and integrated circuitry. In one embodiment, multiple user interface components or peripheral components, or both, couple to interface 914. Network interface 950 provides system 900 the ability to communicate with remote devices (e.g., servers or other computing devices) over one or more networks. Network interface 950 can include an Ethernet adapter, wireless interconnection components, cellular network interconnection components, USB (universal serial bus), or other wired or wireless standards-based or proprietary interfaces. Network interface 950 can exchange data with a remote device, which can include sending data stored in memory or receiving data to be stored in memory.

In one embodiment, system 900 includes one or more input/output (I/O) interface(s) 960. I/O interface 960 can include one or more interface components through which a user interacts with system 900 (e.g., audio, alphanumeric, tactile/touch, or other interfacing). Peripheral interface 970 can include any hardware interface not specifically mentioned above. Peripherals refer generally to devices that connect dependently to system 900. A dependent connection is one where system 900 provides the software platform or hardware platform or both on which operation executes, and with which a user interacts.

In one embodiment, system 900 includes storage subsystem 980 to store data in a nonvolatile manner. In one embodiment, in certain system implementations, at least certain components of storage 980 can overlap with components of memory subsystem 920. Storage subsystem 980 includes storage device(s) 984, which can be or include any conventional medium for storing large amounts of data in a nonvolatile manner, such as one or more magnetic, solid state, or optical based disks, or a combination. Storage 984 holds code or instructions and data 986 in a persistent state (i.e., the value is retained despite interruption of power to system 900). Storage 984 can be generically considered to be a “memory,” although memory 930 is typically the executing or operating memory to provide instructions to processor 910. Whereas storage 984 is nonvolatile, memory 930 can include volatile memory (i.e., the value or state of the data is indeterminate if power is interrupted to system 900). In one embodiment, storage subsystem 980 includes controller 982 to interface with storage 984. In one embodiment controller 982 is a physical part of interface 914 or processor 910 or can include circuits or logic in both processor 910 and interface 914.

Power source 902 provides power to the components of system 900. More specifically, power source 902 typically interfaces to one or multiple power supplies 904 in system 900 to provide power to the components of system 900. In one embodiment, power supply 904 includes an AC to DC (alternating current to direct current) adapter to plug into a wall outlet. Such AC power can be renewable energy (e.g., solar power) power source 902. In one embodiment, power source 902 includes a DC power source, such as an external AC to DC converter. In one embodiment, power source 902 or power supply 904 includes wireless charging hardware to charge via proximity to a charging field. In one embodiment, power source 902 can include an internal battery or fuel cell source.

In one example, the memory 930 can be implemented with 4-way psuedo split DRAM devices in accordance with examples described herein.

Thus, a 4-way Pseudo Split Die DRAM architecture is described herein. In one example, each slice of the DRAM will be either a x2 or x4 depending on the desired width of the DRAM memory channel to provide an SDDC memory configuration within fewer devices than a conventional SDDC compliant memory module. From a form factor perspective, the 4-way pseudo split architecture enables stacking 10 devices into a package to create a memory channel with 2 packages. In one example, the capacity per memory channel can be reduced to improve the memory bandwidth to capacity ratio without sacrificing full SDDC. An alternative advantage is this DRAM style will allow higher bandwidth MRDIMM and CXL DIMM concepts by allowing a lower capacity rank behind the buffer, thereby lowering power while promoting higher speed.

Examples of four way pseudo split die DRAM architectures follow.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

The hardware design embodiments discussed above may be embodied within a semiconductor chip and/or as a description of a circuit design for eventual targeting toward a semiconductor manufacturing process. In the case of the later, such circuit descriptions may take of the form of a (e.g., VHDL or Verilog) register transfer level (RTL) circuit description, a gate level circuit description, a transistor level circuit description or mask description or various combinations thereof. Circuit descriptions are typically embodied on a computer readable storage medium (such as a CD-ROM or other type of storage technology).

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A memory module comprising:
a plurality of dynamic random access memory (DRAM) devices, each of the plurality of DRAM devices including four slices; and
a memory channel including four pseudo channels, each of the four pseudo channels including a corresponding slice of each of the plurality of DRAM devices.

2. The memory module of claim 1, wherein:
the plurality of DRAM devices include a plurality of data devices and at least one error code correction (ECC) device;
wherein each of the four pseudo channels include a corresponding slice from each of the plurality of data devices and from the at least one ECC device.

3. The memory module of claim 1, wherein:
each of the plurality of DRAM devices includes input/output (I/O) interface circuitry to couple with at least one clock signal, at least one command (CA) bus, at least one data strobe signal, and a data bus; and
wherein each of the slices includes a plurality of data lanes to couple with the data bus.

4. The memory module of claim 3, wherein:
each of the slices is configurable to enable 2 or 4 data lanes.

5. The memory module of claim 3, wherein:
the I/O interface circuitry of each of the plurality of DRAM devices is to couple with two CA buses; and
wherein two of the four slices of each of the plurality of DRAM devices share a CA bus.

6. The memory module of claim 3, wherein:
the I/O interface circuitry of each of the plurality of DRAM devices is to couple with two data strobe signal lines; and
wherein two of the four slices of each of the plurality of DRAM devices share a data strobe.

7. The memory module of claim 1, wherein:
two of the four slices of each of the plurality of DRAM devices share one of those slice's data lanes.

8. The memory module of claim 1, wherein:
each of the plurality of DRAM devices includes circuitry to:
for each of the slices, transmit or receive data over a burst.

9. The memory module of claim 1, wherein:
the memory module includes a stacked memory module.

10. The memory module of claim 9, wherein:
the stacked memory module includes two or more packages, the two or more packages including the plurality of DRAM devices.

11. A memory module comprising:
a plurality of dynamic random access memory (DRAM) devices, each of the plurality of DRAM devices including four independent slices; and
a memory channel including four pseudo channels, each of the four pseudo channels including a number of slices of the plurality of DRAM devices equal to the number of DRAM devices.

12. The memory module of claim 11, wherein:
each of the four pseudo channels includes four slices from a single one of the plurality of DRAM devices.

13. The memory module of claim 11, wherein:
each of the four pseudo channels includes one slice from each of the plurality of DRAM devices.

14. The memory module of claim 11, wherein:
the plurality of DRAM devices include a plurality of data devices and at least one error code correction (ECC) device;
wherein each of the four pseudo channels include a corresponding slice from each of the plurality of data devices and from the at least one ECC device.

15. A system comprising:
a processor; and
memory coupled with the processor, the memory including:
a plurality of DRAM devices, each of the plurality of DRAM devices including four slices, and
a memory channel including four pseudo channels, each of the four pseudo channels including a corresponding slice of each of the plurality of DRAM devices.

16. The system of claim 15, wherein:
the plurality of DRAM devices include a plurality of data devices and at least one error code correction (ECC) device;
wherein each of the four pseudo channels include a corresponding slice from each of the plurality of data devices and from the at least one ECC device.

17. The system of claim 15, wherein:
each of the plurality of DRAM devices includes input/output (I/O) interface circuitry to couple with at least one clock signal, at least one command (CA) bus, at least one data strobe signal, and a data bus; and
wherein each of the slices includes a plurality of data lanes to couple with the data bus.

18. The system of claim 15, wherein:
the memory includes a plurality of stacked memory packages including the plurality of DRAM devices.

19. The system of claim 18, wherein:
the plurality of stacked memory packages include at least two packages, wherein the memory channel includes the at least two packages.

20. The system of claim 15, further comprising one or more of:
a memory controller, a power supply, and a display.
